(19) United States
(12) Patent Application Publication
(10) Pub. No.: US 2015/0235953 A1
(43) Pub. Date: Aug. 20, 2015

(54) SEMICONDUCTOR DEVICE AND FORMATION THEREOF

(71) Applicant: Taiwan Semiconductor Manufacturing Company Limited, Hsin-Chu (TW)

(72) Inventors: Jung-Chih Tsao, Tainan City (TW); Chi-Cheng Hung, Tainan City (TW); Yu-Sheng Wang, Tainan City (TW); Shih-Chieh Chang, Taipei City (TW); Wen-Hsi Lee, Kaohsiung City (TW); Ying-Lang Wang, Tien-Chung Village (TW)

(21) Appl. No.: 14/180,388

(22) Filed: Feb. 14, 2014

(51) Int. Cl. H01L 23/532; H01L 21/768; H01L 23/528

(52) U.S. Cl. CPC H01L 23/53238; H01L 23/528; H01L 21/76879; H01L 21/76886; H01L 21/76843; H01L 21/76873

(57) ABSTRACT

A semiconductor device and method of formation are provided. A semiconductor device includes a copper fill over a first layer in a first opening. The first layer includes cobalt and tungsten. A third layer including cobalt and tungsten is over the copper fill and the first layer. The first layer including cobalt and tungsten has a smoother sidewall than a first layer that does not have cobalt or tungsten. A smoother sidewall decreases defects in the copper fill, thus increasing conductivity of the copper fill. The first layer and the third layer reduce out diffusion of copper from the copper fill as compared to a semiconductor device that does not comprise such layers.

### BACKGROUND

Contacts or wire are used to make electrical connections in semiconductor arrangements. Such contacts are formed of conductive materials, such as copper. In certain conditions, copper diffuses out into surrounding materials, which decreases semiconductor device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method of forming a semiconductor device, in accordance with some embodiments.

FIG. 2 is an illustration of a semiconductor device, in accordance with some embodiments.

FIG. 3 is an illustration of a semiconductor device, in accordance with some embodiments.

FIG. 4 is an illustration of a semiconductor device, in accordance with some embodiments.

FIG. 5 is an illustration of a semiconductor device, in accordance with some embodiments.

FIG. 6 is an illustration of a semiconductor device, in accordance with some embodiments.

FIG. 7 is an illustration of a semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

One or more techniques for forming a semiconductor device and resulting structures formed thereby are provided herein.

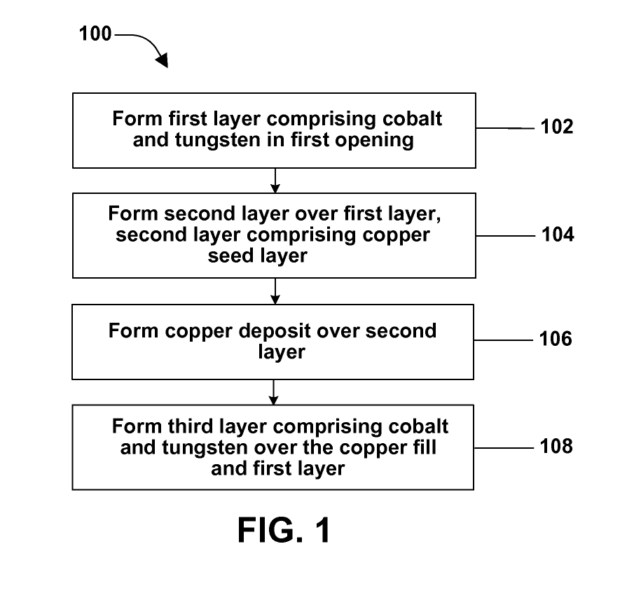

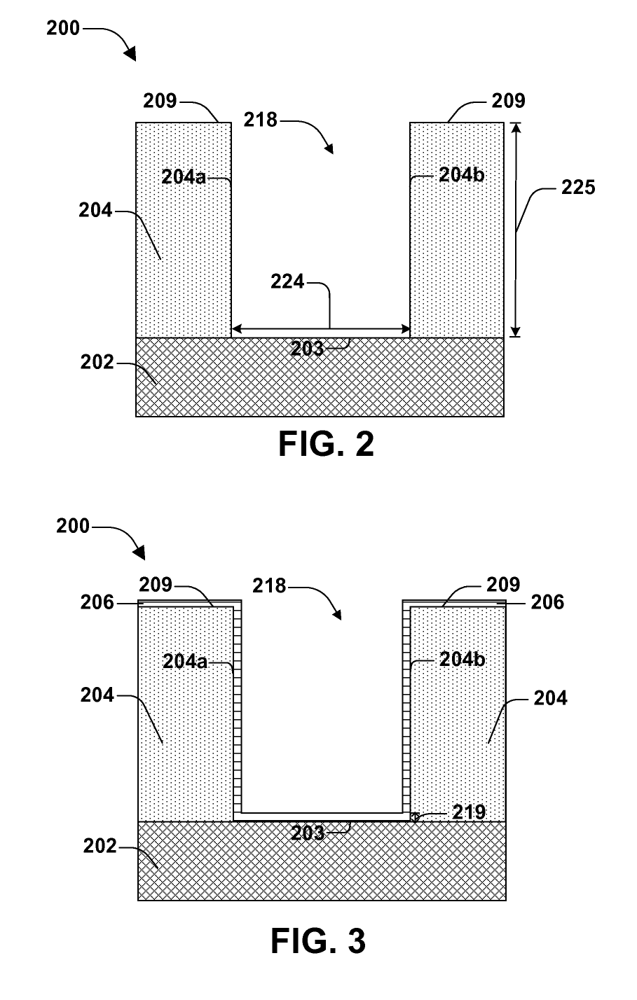

A method 100 of forming a semiconductor device 200 is illustrated in FIG. 1, and one or more semiconductor arrangements formed by such methodology are illustrated in FIGS. 2-7. As illustrated in FIG. 7, a semiconductor device 200 comprises a copper fill 215, where the copper fill 215 comprises a copper deposit 216 and a second layer 213, where the second layer 213 is a copper seed layer, according to some embodiments. In some embodiments, the copper fill 215 is over a first layer 206. In some embodiments, a third layer 214 is over the copper fill 215 and the first layer 206. In some embodiments, the first layer 206 is in contact with a first dielectric sidewall 204a, a second dielectric sidewall 204b and a top surface 203 of a substrate 202. In some embodiments, the first layer 206 comprises cobalt and tungsten and comprises a smoother sidewall than a first layer that does not comprise cobalt and tungsten. In some embodiments, a smoother sidewall decreases defects in the deposited copper fill 215, thus increasing conductivity of the copper fill 215. In some embodiments, the third layer 214 comprises cobalt and tungsten 214. In some embodiments, the first layer 206 and the third layer 214 reduce copper diffusion as compared to a semiconductor device that does not comprise such layers.

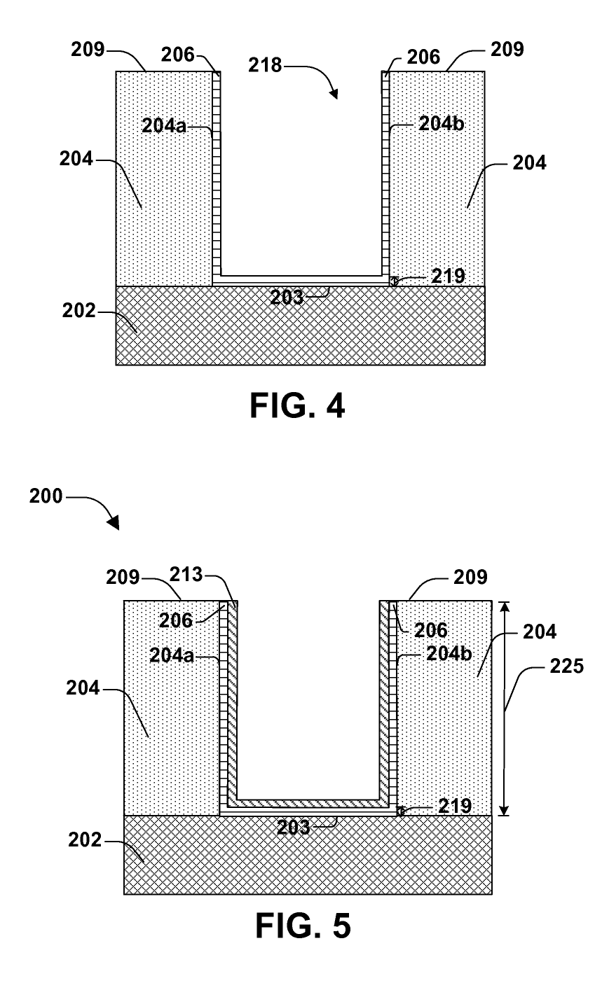

At 102, the first layer 206 comprising cobalt and tungsten is formed in a first opening 218, as illustrated in FIG. 3, according to some embodiments. Turning to FIG. 2, prior to FIG. 3, the first opening 218 is formed via etching, such as a contact dry etch of a dielectric layer 204, according to some embodiments. In some embodiments, the substrate 202 comprises a dielectric, such as oxide, or a metal, such as copper. In some embodiments, the substrate 202 is over an epitaxial layer, a silicon-on-insulator (SOI) structure, a wafer, or a die formed from a wafer. In some embodiments, the dielectric layer 204 comprises at least one of silicon, oxide or nitride. In some embodiments, the first opening 218 has a first width 224. In some embodiments, the first width 224 is measured from the first dielectric sidewall 204a to the second dielectric sidewall 204b defining the first opening 218. In some embodiments, the first width 224 is about 10 μm to about 14 μm. In some embodiments, the first opening 218 has a first depth 225 measured from a top surface 209 of the dielectric layer 204 to the top surface 203 of the substrate 202. In some embodiments, the first depth 225 is about 750 Å to about 1,250 Å. In some embodiments, the first layer 206 is formed conformally within the first opening 218, as illustrated in FIG. 3. In some embodiments, the first layer 206 comprises cobalt (Co) and tungsten (W). In some embodiments, the first layer 206 comprises about 30% to about 70% cobalt and about 30% to about 70% tungsten. In some embodiments, the first layer 206 comprises at least one of an n-type dopant, such as phosphorus, or a p-type dopant, such as boron. In some embodiments, the first layer 206 comprises about 5% to about 15% of at least one of the n-type dopant or the p-type dopant. In some embodiments, the first layer 206 has first thickness 219 of about 5 Å to about 40 Å. In some embodiments, the first layer 206 is formed using atomic layer deposition (ALD). In some embodiments, the first layer 206 is formed in a chamber. In some embodiments, the first layer 206 is formed by introducing a first gas comprising at least one of Ar, H₂, N₂, He or NH₃ into the chamber at a first flow rate of about 1 sccm to about 1000 sccm. In some embodiments, the chamber is at first temperature of about 200° C. to about 800° C. In some embodiments, the chamber is at a first pressure of about 0.5 Torr to about 760 Torr. In some embodiments, the first layer 206 is formed by introducing a cobalt precursor into the chamber. In some embodiments, the first layer 206 is formed by introducing a tungsten precursor into the chamber. In some embodiments, the first layer 206 is formed by introducing at least one of the n-type dopant or the p-type dopant into the chamber. In some embodiments, the first layer 206 is removed from the top surface 209 of the dielectric 204, such as by chemical mechanical planarization (CMP), as illustrated in FIG. 4.

At 104, the second layer 213 is formed over the first layer 206, where the second layer 213 comprises a copper seed layer, as illustrated in FIG. 5, according to some embodiments. In some embodiments, the second layer 213 is formed conformally over the first layer 206. In some embodiments, the second layer 213 is formed by electro-chemical plating (ECP). In some embodiments, ECP comprises plating a copper ion on the first layer 206, where the copper ion is in an electrolyte solution. In some embodiments, the second layer 213 is formed in the same chamber as the first layer 206. In some embodiments, the second layer 213 is formed in a different chamber than the first layer 206. In some embodiments, residual second layer 213 is removed from the top surface 209 of the dielectric 204 by chemical mechanical planarization (CMP), as illustrated in FIG. 5.

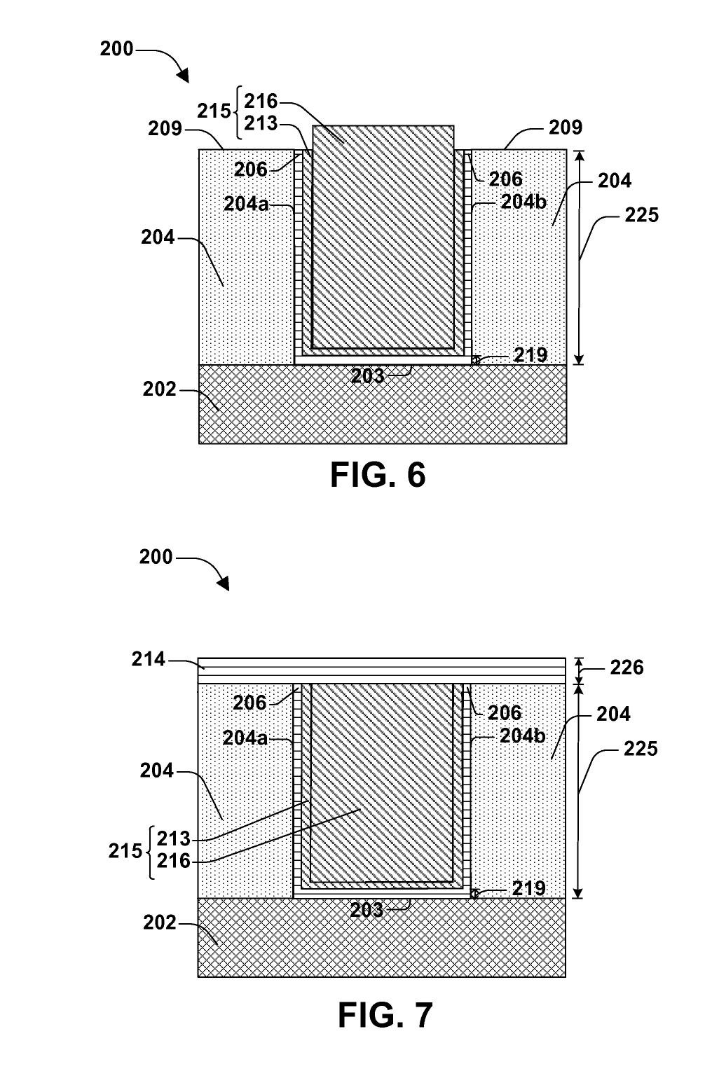

At 106, the copper deposit 216 is formed over the second layer 213 to establish the copper fill 215, as illustrated in FIG. 6, according to some embodiments. In some embodiments, the copper deposit 216 is formed by at least one of physical vapor deposition (PVD), chemical vapor deposition (CVD) or ALD. In some embodiments, the copper deposit 216 is formed in the same chamber as at least one of the second layer 213 or the first layer 206. In some embodiments, the copper deposit 216 is formed in a different chamber than the second layer 213. In some embodiments, the copper deposit 216 has a copper deposit height, such that a copper top surface is above the top surface 209 of the dielectric 204. In some embodiments, the copper deposit height is reduced, such as by CMP, such that the copper top surface is even or planer with the top surface 209 of the dielectric 204, as illustrated in FIG. 7.

At 108, the third layer 214 comprising cobalt and tungsten is formed over the top surface 209 of the dielectric 204, the first layer 206 and the copper fill 215, as illustrated in FIG. 7, according to some embodiments. Although not illustrated, the third layer 214 is removed from the top surface 209, such as by etching, according to some embodiments. In some embodiments, the third layer 214 comprises about 30% to about 70% cobalt and about 30% to about 70% tungsten. In some embodiments, the third layer 214 comprises at least one of an n-type dopant, such as phosphorus, or a p-type dopant, such as boron. In some embodiments, the third layer 214 comprises about 5% to about 15% of at least one of the n-type dopant or the p-type dopant. In some embodiments, the third layer 214 has substantially the same composition as the first layer 206. In some embodiments, the third layer 214 has a different composition as the first layer 206. In some embodiments, the third layer 214 has third thickness 226 of about 10 Å to about 60 Å, the third thickness 226 greater than the first thickness 219. In some embodiments, the third layer 214 is formed using ALD. In some embodiments, the third layer 214 is formed in a chamber. In some embodiments, the third layer 214 is formed in the same chamber as at least one of the second layer 213, the first layer 206 or the copper deposit 216. In some embodiments, the third layer 214 is formed in a different chamber than the copper deposit 216. In some embodiments, the third layer 214 is formed by introducing a second gas comprising at least one of Ar, H₂, N₂, He or NH₃ into the chamber at a second flow rate of about 1 sccm to about 1000 sccm. In some embodiments, the chamber is at second temperature of about 200° C. to about 800° C. In some embodiments, the chamber is at a second pressure of about 0.5 Torr to about 760 Torr. In some embodiments, the third layer 214 is formed by introducing the cobalt precursor into the chamber. In some embodiments, the third layer 214 is formed by introducing the tungsten precursor into the chamber. In some embodiments, the third layer 214 is formed by introducing at least one of the n-type dopant or the p-type dopant into the chamber. In some embodiments, the first layer 206 comprising cobalt and tungsten comprises a smoother sidewall than a first layer that does not comprises cobalt or tungsten. In some embodiments, a smoother sidewall decreases defects in the copper fill 215, thus increasing conductivity of the copper fill 215. In some embodiments, the first layer 206 and the third layer 214 reduce out diffusion of copper from the copper fill 215 as compared to a semiconductor device that does not comprise such layers.

According to some embodiments, a semiconductor device comprises a first layer comprising cobalt and tungsten in a first opening. In some embodiments, a copper fill is over the first layer in the first opening.

According to some embodiments, a method of forming a semiconductor device comprises forming a first layer comprising cobalt and tungsten in a first opening and forming a copper fill over the first layer in the first opening.

According to some embodiments, a semiconductor device comprises a first layer comprising cobalt and tungsten in a first opening. In some embodiments, a copper fill is over the first layer in the first opening. In some embodiments, a third layer is over the copper fill, the third layer comprising cobalt and tungsten.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming the layers features, elements, etc. mentioned herein, such as etching techniques, implanting techniques, doping techniques, spin-on techniques, sputtering techniques such as magnetron or ion beam sputtering, growth techniques, such as thermal growth or deposition techniques such as chemical vapor deposition (CVD), physical vapor deposition (PVD), plasma enhanced chemical vapor deposition (PECVD), or atomic layer deposition (ALD), for example.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others skilled in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A semiconductor device comprising:
a first layer comprising cobalt and tungsten in a first opening; and
a copper fill over the first layer in the first opening.

2. The semiconductor device of claim 1, wherein the copper fill comprises a second layer, the second layer comprising a copper seed layer.

3. The semiconductor device of claim 1, comprising a third layer over the copper fill, the third layer comprising cobalt and tungsten.

4. The semiconductor device of claim 3, wherein the first layer has a first thickness and the third layer has a third thickness, the third thickness greater than the first thickness.

5. The semiconductor device of claim 1, wherein the first layer comprises about 30% to about 70% cobalt and about 30% to about 70% tungsten.

6. The semiconductor device of claim 5, wherein the first layer comprises at least one of an n-type dopant or a p-type dopant.

7. The semiconductor device of claim 6, wherein the first layer comprises about 5% to about 15% of at least one of the n-type dopant or the p-type dopant.

8. The semiconductor device of claim 1, wherein the first opening is defined by a first sidewall of a dielectric, a second sidewall of the dielectric, and a top surface of a substrate.

9. The semiconductor device of claim 8, wherein the substrate comprises at least one of a metal or dielectric.

10. A method of forming a semiconductor device comprising:
forming a first layer comprising cobalt and tungsten in a first opening; and
forming a copper fill over the first layer in the first opening.

11. The method of claim 10, wherein the forming a copper fill comprises forming a second layer in the opening over the first layer, the second layer comprising a copper seed layer.

12. The method of claim 11, wherein the forming a second layer comprises forming the second layer by electrochemical plating.

13. The method of claim 10, comprising forming a third layer comprising cobalt and tungsten over the copper fill.

14. The method of claim 10, wherein the forming a first layer comprises forming the first layer by atomic layer deposition (ALD).

15. The method of claim 10, wherein the forming a first layer comprises introducing a first gas comprising at least one of Ar, H₂, N₂, He or NH₃ into a chamber at a first flow rate of about 1 sccm to about 1000 sccm, the chamber at first temperature of about 200° C. to about 800° C. and a first pressure of about 0.5 Torr to about 760 Torr.

16. The method of claim 10, wherein the first layer is formed using a cobalt precursor and a tungsten precursor.

17. The method of claim 16, wherein the first layer is formed using at least one of an n-type dopant or a p-type dopant.

18. A semiconductor device comprising:
a first layer comprising cobalt and tungsten in a first opening;
a copper fill over the first layer in the first opening; and
a second layer over the copper fill, the second layer comprising cobalt and tungsten.

19. The semiconductor device of claim 18, wherein at least one of the first layer or the second layer comprises about 30% to about 70% cobalt and about 30% to about 70% tungsten.

20. The semiconductor device of claim 18, wherein at least one of the first layer or the second layer comprises about 5% to about 15% of at least one of an n-type dopant or a p-type dopant.
